(19) United States
(12) Patent Application Publication
(10) Pub. No.: US 2025/0020701 A1
(43) Pub. Date: Jan. 16, 2025

(54) OPERATIONAL STATUS DETERMINING APPARATUS, METHOD, AND RECORDING MEDIUM

(71) Applicant: Allied Telesis Holdings K.K., Tokyo (JP)

(72) Inventor: Takuya Negishi, Tokyo (JP)

(21) Appl. No.: 18/646,384

(22) Filed: Apr. 25, 2024

(30) Foreign Application Priority Data
Jul. 12, 2023 (JP) 2023-114256

(51) Int. Cl. G01R 19/165; G01R 15/22

(52) U.S. Cl. CPC G01R 19/16571; G01R 15/22

(57) ABSTRACT

An operational status determining apparatus includes a current measuring section, and an on/off determining section. The current measuring section measures a current through a power cable connected to an electrical equipment. The on/off determining section determines that the electrical equipment is powered on when the current is higher than a threshold value, while determines that the electrical equipment is powered off when the current is lower than the threshold value. The threshold value is equal to or higher than a current upper limit below which the electrical equipment is definitely powered off, and equal to or lower than a current lower limit above which the electrical equipment is definitely powered on.

### CROSS-REFERENCE TO RELATED APPLICATION

This application claims the priority benefit of Japanese Application Serial Number 2023-114256 filed Jul. 12, 2023, which is incorporated herein by reference in its entirety for all purposes.

### BACKGROUND OF THE INVENTION

### Field of the Invention

The present invention relates to determining the operational status of electrical equipment.

### Description of the Related Art

There has conventionally been known a technique of determining the operational status of an electrical appliance connected to a power cable by detecting an alternating current flowing through the power cable (see paragraphs to of Japanese Patent Application Publication No. 2006-109634, for example).

### SUMMARY OF THE INVENTION

In accordance with the related art above, it is, however, not clear that the electrical equipment connected to the power cable can be considered operating depending on how large is the alternating current flowing through the power cable. That is, no threshold value for the alternating current flowing through the power cable is defined to determine whether or not the electrical equipment is operating.

It is hence an object of the present invention to provide a threshold value for a current flowing through a power cable to determine whether or not electrical equipment connected to the power cable is operating.

According to the present invention, an operational status determining apparatus, includes: a current measuring section arranged to measure a current through a power cable connected to an electrical equipment; and an on/off determining section arranged to determine that the electrical equipment is powered on when the current is higher than a threshold value, while determine that the electrical equipment is powered off when the current is lower than the threshold value, wherein the threshold value is: equal to or higher than a current upper limit below which the electrical equipment is definitely powered off, and equal to or lower than a current lower limit above which the electrical equipment is definitely powered on.

According to the thus constructed operational status determining apparatus, a current measuring section measures a current through a power cable connected to an electrical equipment. An on/off determining section determines that the electrical equipment is powered on when the current is higher than a threshold value, while determines that the electrical equipment is powered off when the current is lower than the threshold value. The threshold value is: equal to or higher than a current upper limit below which the electrical equipment is definitely powered off, and equal to or lower than a current lower limit above which the electrical equipment is definitely powered on.

According to the operational status determining apparatus of the present invention, the current measuring section may be a non-contact sensor not in contact with the power cable.

According to the present invention, the operational status determining apparatus may further include: a threshold value deriving section arranged to derive the threshold value; an on-current deriving section arranged to derive an on-current value at which the electrical equipment is powered on; and an off-current deriving section arranged to derive an off-current value at which the electrical equipment is powered off, wherein the threshold value deriving section is arranged to subtract the off-current value from the on-current value and multiply by a predetermined coefficient to derive the threshold value.

According to the operational status determining apparatus of the present invention, the on-current deriving section may be arranged to derive the on-current value as an average of measurements of the current.

According to the operational status determining apparatus of the present invention, the on-current deriving section may be arranged to, when the average of measurements of the current is higher than the on-current value+(a maximum of measurements of the current within a predetermined period of time−a minimum of measurements of the current within a predetermined period of time)/2, set the average of measurements of the current as a new on-current value.

According to the operational status determining apparatus of the present invention, the off-current deriving section may be arranged to derive the off-current value as an average of measurements of the current.

According to the operational status determining apparatus of the present invention, the off-current deriving section may be arranged to, when the average of measurements of the current is lower than the off-current value−(a maximum of measurements of the current within a predetermined period of time−a minimum of measurements of the current within a predetermined period of time)/2, set the average of measurements of the current as a new off-current value.

According to the operational status determining apparatus of the present invention, the off-current deriving section may be arranged to derive the off-current value as a mode of measurements of the current within a period of time within which the electrical equipment is powered off.

According to the present invention, the operational status determining apparatus may further include: an on-current derivation instructing section arranged to instruct the on-current deriving section to derive the on-current value; and an off-current derivation instructing section arranged to instruct the off-current deriving section to derive the off-current value, wherein the on-current derivation instructing section and the off-current derivation instructing section are separate from each other.

According to the present invention, the operational status determining apparatus may further include an on/off-current derivation instructing section arranged to instruct the on-current deriving section and the off-current deriving section for derivation, wherein the on/off-current derivation instructing section is arranged to: when receiving a first operation, instruct the on-current deriving section for derivation, while when receiving a second operation, instruct the off-current deriving section for derivation.

According to the present invention, the operational status determining apparatus may further include a notifying section arranged to notify that the on/off-current derivation instructing section receives the first operation or the second operation.

According to the present invention, an operational status determining method for determining an operational status of an electrical equipment with using a current measuring section arranged to measure a current through a power cable connected to the electrical equipment, includes: determining that the electrical equipment is powered on when the current is higher than a threshold value, while determining that the electrical equipment is powered off when the current is lower than the threshold value, wherein the threshold value is: equal to or higher than a current upper limit below which the electrical equipment is definitely powered off, and equal to or lower than a current lower limit above which the electrical equipment is definitely powered on.

The present invention is a non-transitory computer-readable medium including a program of instructions for execution by a computer to perform an operational status determining process for determining an operational status of an electrical equipment with using a current measuring section arranged to measure a current through a power cable connected to the electrical equipment, the operational status determining process including: determining that the electrical equipment is powered on when the current is higher than a threshold value, while determining that the electrical equipment is powered off when the current is lower than the threshold value, wherein the threshold value is: equal to or higher than a current upper limit below which the electrical equipment is definitely powered off, and equal to or lower than a current lower limit above which the electrical equipment is definitely powered on.

### BRIEF DESCRIPTION OF THE DRAWINGS

FIG. 1 illustrates an environment in which a sensor tag (operational status determining apparatus) 1 according to an embodiment of the present invention is used;

FIG. 2 is a functional block diagram illustrating the configuration of a sensor tag (operational status determining apparatus) 1 according to a first embodiment;

FIG. 3 is an illustrative view for explaining a threshold value Ath;

FIG. 4 is a functional block diagram illustrating the configuration of a sensor tag (operational status determining apparatus) 1 according to the second embodiment;

FIG. 5 is a functional block diagram illustrating the configuration of an on-current deriving section 14 according to the third embodiment;

FIG. 6 is a functional block diagram illustrating the configuration of an off-current deriving section 16 according to the third embodiment; and

FIG. 7 is a functional block diagram illustrating the configuration of a sensor tag (operational status determining apparatus) 1 according to the fourth embodiment.

### DESCRIPTION OF THE PREFERRED EMBODIMENTS

Preferred embodiments of the present invention will hereinafter be described with reference to the accompanying drawings.

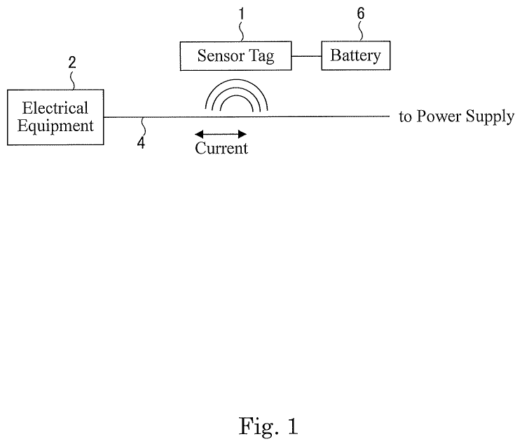

FIG. 1 illustrates an environment in which a sensor tag (operational status determining apparatus) 1 according to an embodiment of the present invention is used.

An electrical equipment 2 is a home appliance such as, for example, a display or a compact fan. The electrical equipment 2 is connected with a power cable 4. The electrical equipment 2 is connected through the power cable 4 to a power supply not shown. When the electrical equipment 2 is on, an alternating current flows through the power cable 4.

The sensor tag (operational status determining apparatus) 1 is connected to and powered by a battery 6. The sensor tag 1 is arranged to receive electromagnetic radiation generated when a current flows through the power cable 4 and determine an operational status (on or off) of the electrical equipment 2.

It is noted that the above-described environment in which the sensor tag 1 is used is common to the following various embodiments.

### First Embodiment

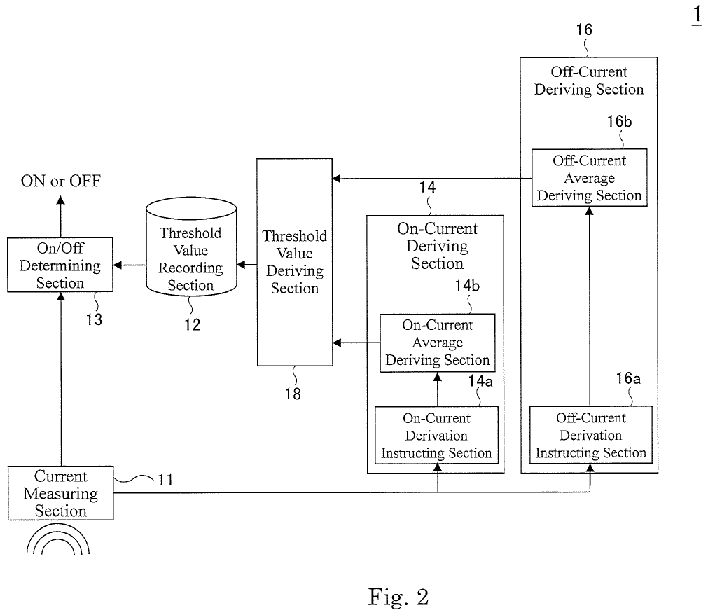

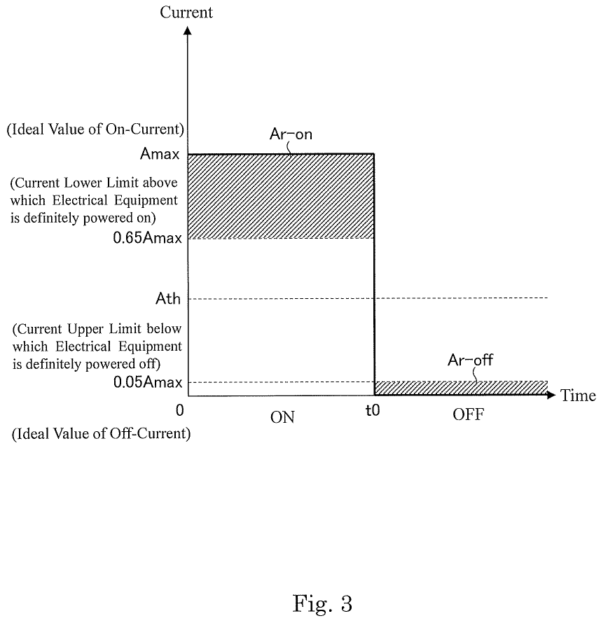

FIG. 2 is a functional block diagram illustrating the configuration of a sensor tag (operational status determining apparatus) 1 according to a first embodiment. FIG. 3 is an illustrative view for explaining a threshold value Ath.

The sensor tag (operational status determining apparatus) 1 according to the first embodiment includes a current measuring section 11, a threshold value recording section 12, an on/off determining section 13, an on-current deriving section 14, an off-current deriving section 16, and a threshold value deriving section 18.

The current measuring section 11 is arranged to measure a current through the power cable 4 connected to the electrical equipment 2. The current measuring section 11 is a non-contact sensor not in contact with the power cable 4.

The threshold value recording section 12 is arranged to record a threshold value Ath.

The on/off determining section 13 is arranged to determine that the electrical equipment 2 is powered on when the current is higher than the threshold value Ath, while determine that the electrical equipment 2 is powered off when the current is lower than the threshold value Ath. It is noted that the on/off determining section 13 is arranged to determine that the electrical equipment 2 is powered off when the current is equal to the threshold value Ath (though may be arranged to determine that the electrical equipment 2 is powered on).

The threshold value Ath is equal to or higher than a current upper limit (e.g. 0.05 Amax) below which the electrical equipment 2 is definitely powered off, and equal to or lower than a current lower limit (e.g. 0.65 Amax) above which the electrical equipment 2 is definitely powered on. This will be described in more detail below with reference to FIG. 3.

The on-current deriving section 14 is arranged to derive an on-current value at which the electrical equipment 2 is powered on. The off-current deriving section 16 is arranged to derive an off-current value at which the electrical equipment 2 is powered off. The threshold value deriving section 18 is arranged to derive the threshold value Ath. The threshold value deriving section 18 is arranged to subtract the off-current value (e.g. 0) from the on-current value (e.g. Amax) and multiply by a predetermined coefficient (e.g. a value equal to or higher than 0.05 but equal to or lower than 0.65) to derive the threshold value Ath (see FIG. 3).

With reference to FIG. 3, it is here assumed that the electrical equipment 2 is powered on from time 0 to t0, while powered off after time t0. Note here that the vertical axis in FIG. 3 represents a result of measurement by the current measuring section 11, while the horizontal axis in FIG. 3 represents time.

The current measuring section 11 then outputs an on-current as a result of measurement from time 0 to t0. It is here assumed for the purpose of illustration that in FIG. 3, the on-current is in an ideal state of having a predetermined constant value Amax. On the other hand, the current measuring section 11 outputs an off-current as a result of measurement after time t0. It is here assumed for the purpose of illustration that in FIG. 3, the off-current is in an ideal state of constantly 0.

Incidentally, when the electrical equipment 2 is powered on, circuits within the electrical equipment 2 consume or do not consume currents where appropriate. This causes increased fluctuation in the on-current value. Accordingly, the electrical equipment 2 can be presumed to be powered on even if the result of measurement by the current measuring section 11 may be significantly lower than Amax. For example, the electrical equipment 2 can be presumed to be powered on as long as the result of measurement by the current measuring section 11 is equal to or higher than 0.65 Amax (=0.65×(Amax−0)). 0.65 Amax is thus a current lower limit above which the electrical equipment 2 is definitely powered on. It is noted that FIG. 3 shows, as Ar-on, an area within which the electrical equipment 2 is definitely powered on.

On the other hand, when the electrical equipment 2 is powered off, circuits within the electrical equipment 2 are approximately deactivated to stand by with minimum power until powered on. This causes decreased fluctuation in the off-current value. Accordingly, the electrical equipment 2 can be presumed to be powered off even if the result of measurement by the current measuring section 11 may be slightly higher than 0. For example, the electrical equipment 2 can be presumed to be powered off as long as the result of measurement by the current measuring section 11 is equal to or lower than 0.05 Amax (=0.05×(Amax−0)). 0.05 Amax is thus a current upper limit above which the electrical equipment 2 is definitely powered off. It is noted that FIG. 3 shows, as Ar-off, an area within which the electrical equipment 2 is definitely powered off.

Here, the threshold value Ath is equal to or higher than 0.05 Amax but equal to or lower than 0.65 Amax. For example, the threshold value Ath is equal to 0.5 Amax.

It is noted that the description of FIG. 3 assumes that the on-current and the off-current are constant. However, the on-current and the off-current actually fluctuate. Hence, an average of measurements of the current by the current measuring section 11 is employed as an on-current or an off-current.

The on-current deriving section 14 is arranged to derive the on-current value as an average of measurements of the current by the current measuring section 11. The on-current deriving section 14 has an on-current derivation instructing section 14a and an on-current average deriving section 14b.

The on-current derivation instructing section 14a is arranged to instruct the on-current average deriving section 14b of the on-current deriving section 14 to derive the on-current value. The on-current average deriving section 14b is arranged to derive the average of measurements of the current by the current measuring section 11 as an on-current and provide it to the threshold value deriving section 18.

It is noted that the on-current derivation instructing section 14a is, for example, a button to be pressed down by a user. Upon the user pressing down the button after verifying that the electrical equipment 2 is powered on, an instruction to derive the on-current value is provided.

The off-current deriving section 16 is arranged to derive the off-current value as an average of measurements of the current by the current measuring section 11. The off-current deriving section 16 has an off-current derivation instructing section 16a and an off-current average deriving section 16b.

The off-current derivation instructing section 16a is arranged to instruct the off-current average deriving section 16b of the off-current deriving section 16 to derive the off-current value. The off-current average deriving section 16b is arranged to derive the average of measurements of the current by the current measuring section 11 as an off-current and provide it to the threshold value deriving section 18.

It is noted that the off-current derivation instructing section 16a is, for example, a button to be pressed down by a user. Upon the user pressing down the button after verifying that the electrical equipment 2 is powered off, an instruction to derive the off-current value is provided.

In addition, the on-current derivation instructing section 14a and the off-current derivation instructing section 16a are separate from each other (e.g. separate buttons).

Next will be described an operation according to the first embodiment.

First, the electrical equipment 2 is powered on. Here, upon the user operating the on-current derivation instructing section 14a (pressing down the button) after verifying that the electrical equipment 2 is powered on, the on-current average deriving section 14b is instructed to derive an on-current value. The on-current average deriving section 14b derives an average of measurements of the current by the current measuring section 11 as an on-current and provides it to the threshold value deriving section 18.

Next, the electrical equipment 2 is powered off. Here, upon the user operating the off-current derivation instructing section 16a (pressing down the button) after verifying that the electrical equipment 2 is powered off, the off-current average deriving section 16b is instructed to derive an off-current value. The off-current average deriving section 16b derives an average of measurements of the current by the current measuring section 11 as an off-current and provides it to the threshold value deriving section 18.

The threshold value deriving section 18 subtracts the off-current value (e.g. 0) from the on-current value (e.g. Amax) and multiply by a predetermined coefficient (e.g. a value equal to or higher than 0.05 but equal to or lower than 0.65) to derive a threshold value Ath and provides it to the threshold value recording section 12.

Here, the current measuring section 11 measures a current with the operational status (on or off) of the electrical equipment 2 unknown. A result of measurement of the current is provided to the on/off determining section 13. When the current is higher than the threshold value Ath, the on/off determining section 13 determines that the electrical equipment 2 is powered on. When the current is lower than the threshold value Ath, the on/off determining section 13 determines that the electrical equipment 2 is powered off.

In accordance with the sensor tag 1 according to the first embodiment, the threshold value Ath for the current flowing through the power cable 4 is derived by the threshold value deriving section 18 to determine whether or not the electrical equipment 2 connected to the power cable 4 is operating, the threshold value Ath being equal to or higher than a current upper limit below which the electrical equipment 2 is definitely powered off and equal to or lower than a current lower limit above which the electrical equipment 2 is definitely powered on.

### Second Embodiment

The sensor tag (operational status determining apparatus) 1 according to a second embodiment differs from that according to the first embodiment in that the former includes an on/off-current derivation instructing section 15 instead of the on-current derivation instructing section 14a and the off-current derivation instructing section 16a.

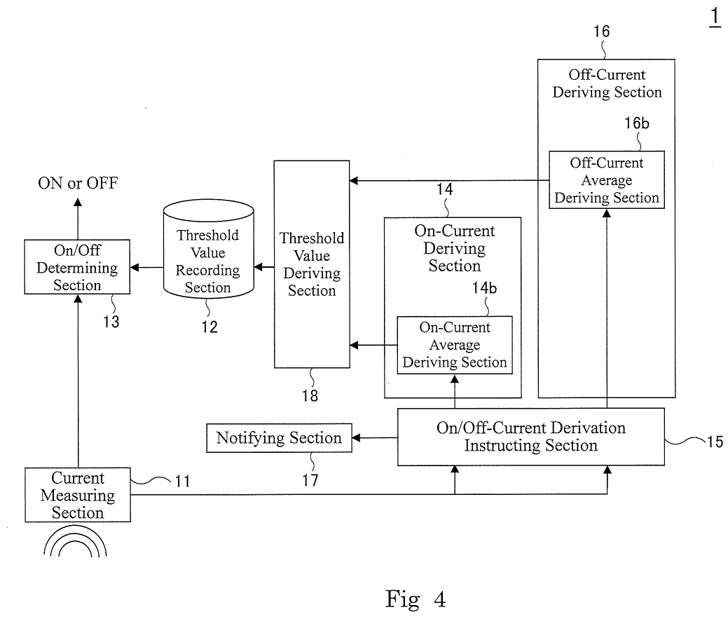

FIG. 4 is a functional block diagram illustrating the configuration of a sensor tag (operational status determining apparatus) 1 according to the second embodiment. The sensor tag 1 according to the second embodiment includes a current measuring section 11, a threshold value recording section 12, an on/off determining section 13, an on-current deriving section 14, an on/off-current derivation instructing section 15, an off-current deriving section 16, a notifying section 17, and a threshold value deriving section 18. Components identical to those in the first embodiment will hereinafter be designated by the same reference symbols to omit the description thereof.

The current measuring section 11, the threshold value recording section 12, the on/off determining section 13, and the threshold value deriving section 18 are identical to those in the first embodiment and will not be described.

The on-current deriving section 14 has an on-current average deriving section 14b but not an on-current derivation instructing section 14a.

The off-current deriving section 16 has an off-current average deriving section 16b but not an off-current derivation instructing section 16a.

The on/off-current derivation instructing section 15 is arranged to instruct the on-current average deriving section 14b of the on-current deriving section 14 and the off-current average deriving section 16b of the off-current deriving section 16 for derivation.

Note here that the on/off-current derivation instructing section 15 is arranged to, when receiving a first operation, instruct the on-current deriving section 14 for derivation, while when receiving a second operation, instruct the off-current deriving section 16 for derivation.

Here, the on/off-current derivation instructing section 15 is, for example, a button to be pressed down by a user. In addition, the first operation is, for example, the second (and fourth, sixth, . . . ) press-down of the button, while the second operation is, for example, the first (and third, fifth, . . . ) press-down of the button.

Note here that the user performs the second operation after verifying that the electrical equipment 2 is powered off. The user also performs the first operation after verifying that the electrical equipment 2 is powered on.

The notifying section 17 is arranged to notify the user that the on/off-current derivation instructing section 15 receives the first operation or the second operation. The notifying section 17 is, for example, a display arranged to show the user an indication that the first operation is received (i.e. an on-current is derived) or an indication that the second operation is received (i.e. an off-current is derived).

Next will be described an operation according to the second embodiment.

First, the electrical equipment 2 is powered off. Here, upon the user operating the on/off-current derivation instructing section 15 (the first press-down of the button) after verifying that the electrical equipment 2 is powered off, the off-current average deriving section 16b is instructed to derive an off-current value. In addition, the notifying section 17 notifies the user that the second operation is received (i.e. an off-current is derived). Further, the off-current average deriving section 16b derives an average of measurements of the current by the current measuring section 11 as an off-current and provides it to the threshold value deriving section 18.

Next, the electrical equipment 2 is powered on. Here, upon the user operating the on/off-current derivation instructing section 15 (the second press-down of the button) after verifying that the electrical equipment 2 is powered on, the on-current average deriving section 14b is instructed to derive an on-current value. In addition, the notifying section 17 notifies the user that the first operation is received (i.e. an on-current is derived). Further, the on-current average deriving section 14b derives an average of measurements of the current by the current measuring section 11 as an on-current and provides it to the threshold value deriving section 18.

The threshold value deriving section 18 subtracts the off-current value (e.g. 0) from the on-current value (e.g. Amax) and multiply by a predetermined coefficient (e.g. a value equal to or higher than 0.05 but equal to or lower than 0.65) to derive a threshold value Ath and provides it to the threshold value recording section 12.

The followed operations (i.e., determining the operational status (on or off) of the electrical equipment 2) are identical to those in the first embodiment and will not be described.

The sensor tag 1 according to the second embodiment exhibits the same advantageous effects as that according to the first embodiment by using the on/off-current derivation instructing section 15 (e.g. one button) instead of the on-current derivation instructing section 14a and the off-current derivation instructing section 16a (e.g. two buttons in total).

### Third Embodiment

The sensor tag (operational status determining apparatus) 1 according to a third embodiment differs from that according to the first embodiment in that the on-current deriving section 14 and the off-current deriving section 16 automatically update the on-current value and the off-current value, respectively.

The sensor tag (operational status determining apparatus) 1 according to the third embodiment includes a current measuring section 11, a threshold value recording section 12, an on/off determining section 13, an on-current deriving section 14, an off-current deriving section 16, and a threshold value deriving section 18. Components identical to those in the first embodiment will hereinafter be designated by the same reference symbols to omit the description thereof.

The current measuring section 11, the threshold value recording section 12, the on/off determining section 13, and the threshold value deriving section 18 are identical to those in the first embodiment and will not be described.

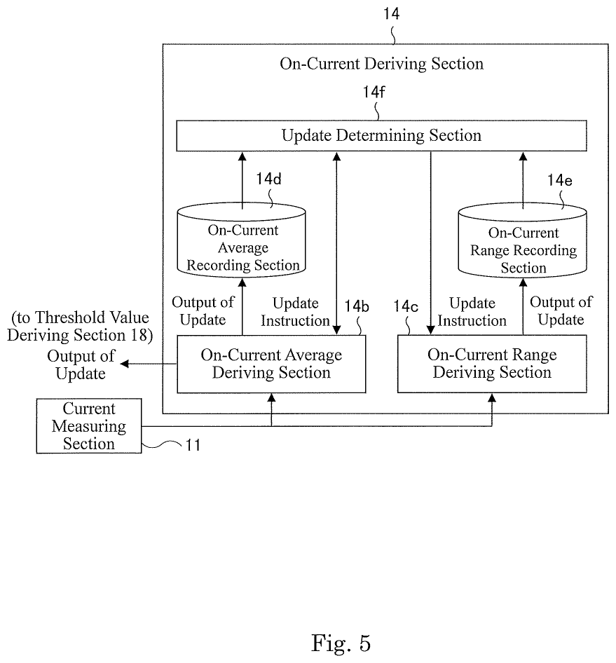

FIG. 5 is a functional block diagram illustrating the configuration of an on-current deriving section 14 according to the third embodiment. The on-current deriving section 14 has an on-current average deriving section 14b, an on-current range deriving section 14c, an on-current average recording section 14d, an on-current range recording section 14e, and an update determining section 14f.

The on-current average deriving section 14b is arranged to derive an average of measurements of the current by the current measuring section 11 within a predetermined period of time (e.g. 5 seconds) as an on-current. The first derived on-current is provided to the threshold value deriving section 18 and the on-current average recording section 14d.

The on-current average deriving section 14b is arranged to derive an average repeatedly (e.g. derive an average of measurements from time t=0 to 5 seconds, derive an average of measurements from time t=5 to 10 seconds, derive an average of measurements from time t=10 to 15 seconds, and so on), during which upon update instruction received from the update determining section 14f, the derived on-current is also provided to the threshold value deriving section 18 and the on-current average recording section 14d.

The on-current range deriving section 14c is arranged to derive a value (i.e., a range of measurements) by subtracting a minimum from a maximum of measurements within a predetermined period of time (e.g., 5 seconds) of the current by the current measuring section 11. The first derived range of measurements is provided to the on-current range recording section 14e.

The on-current range deriving section 14c is also arranged to derive a range of measurements repeatedly (e.g. derive a range of measurements from time t=0 to 5 seconds, derive a range of measurements from time t=5 to 10 seconds, derive a range of measurements from time t=10 to 15 seconds, and so on), during which upon update instruction received from the update determining section 14f, the derived range (a value obtained by subtracting a minimum from a maximum) is also provided to the on-current range recording section 14e.

The on-current average recording section 14d is arranged to record an output from the on-current average deriving section 14b. The on-current range recording section 14e is arranged to record an output from the on-current range deriving section 14c.

The update determining section 14f is arranged to, when the output from the on-current average deriving section 14b (average of measurements of the current) is higher than the recorded content of the on-current average recording section 14d (on-current value)+(the recorded content of the on-current range recording section 14e)/2, provide an update instruction to the on-current average deriving section 14b and the on-current range deriving section 14c. The average of measurements of the current derived by the on-current average deriving section 14b is thus provided as a new on-current value to the threshold value deriving section 18.

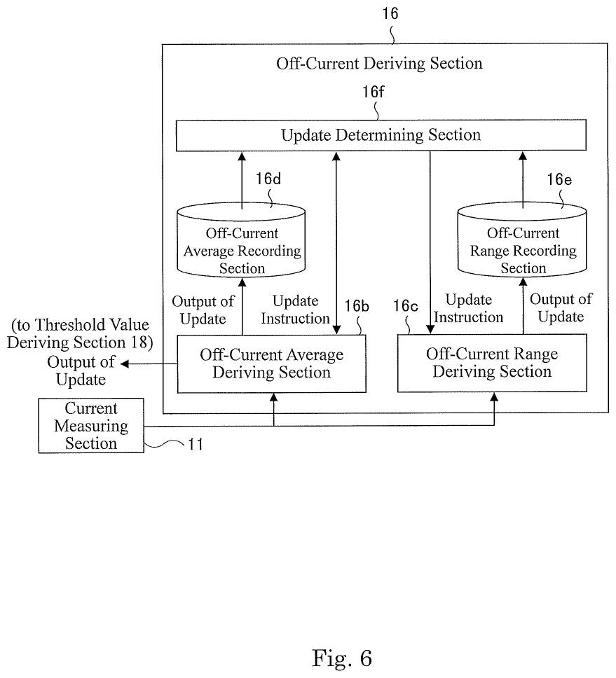

FIG. 6 is a functional block diagram illustrating the configuration of an off-current deriving section 16 according to the third embodiment. The off-current deriving section 16 has an off-current average deriving section 16b, an off-current range deriving section 16c, an off-current average recording section 16d, an off-current range recording section 16e, and an update determining section 16f.

The off-current average deriving section 16b is arranged to derive an average of measurements of the current by the current measuring section 11 within a predetermined period of time (e.g. 5 seconds) as an off-current. The first derived off-current is provided to the threshold value deriving section 18 and the off-current average recording section 16d.

The off-current average deriving section 16b is arranged to derive an average repeatedly (e.g. derive an average of measurements from time t=0 to 5 seconds, derive an average of measurements from time t=5 to 10 seconds, derive an average of measurements from time t=10 to 15 seconds, and so on), during which upon update instruction received from the update determining section 16f, the derived off-current is also provided to the threshold value deriving section 18 and the off-current average recording section 16d.

The off-current range deriving section 16c is arranged to derive a value (i.e., a range of measurements) by subtracting a minimum from a maximum of measurements within a predetermined period of time (e.g., 5 seconds) of the current by the current measuring section 11. The first derived range of measurements is provided to the off-current range recording section 16e.

The off-current range deriving section 16c is also arranged to derive a range of measurements repeatedly (e.g. derive a range of measurements from time t=0 to 5 seconds, derive a range of measurements from time t=5 to 10 seconds, derive a range of measurements from time t=10 to 15 seconds, and so on), during which upon update instruction received from the update determining section 16f, the derived range (a value obtained by subtracting a minimum from a maximum) is also provided to the off-current range recording section 16e.

The off-current average recording section 16d is arranged to record an output from the off-current average deriving section 16b. The off-current range recording section 16e is arranged to record an output from the off-current range deriving section 16c.

The update determining section 16f is arranged to, when the output from the off-current average deriving section 16b (average of measurements of the current) is lower than the recorded content of the off-current average recording section 16d (off-current value)−(the recorded content of the off-current range recording section 16e)/2, provide an update instruction to the off-current average deriving section 16b and the off-current range deriving section 16c. The average of measurements of the current derived by the off-current average deriving section 16b is thus provided as a new off-current value to the threshold value deriving section 18.

Next will be described an operation according to the third embodiment.

(1) In the case the electrical equipment 2 is switched from power-off to power-on

In this case, the average of measurements derived by the on-current average recording section 14d continues to increase significantly. Accordingly, the output from the on-current average deriving section 14b (average of measurements of the current) continues to be higher than the recorded content of the on-current average recording section 14d (on-current value)+(the recorded content of the on-current range recording section 14e)/2. This results in that the on-current value provided to the threshold value deriving section 18 continues to be updated.

However, some time after the electrical equipment 2 is powered on, the current becomes approximately constant. The output from the on-current average deriving section 14b (average of measurements of the current) then no longer exceeds the recorded content of the on-current average recording section 14d (on-current value)+(the recorded content of the on-current range recording section 14e)/2. This results in that the o n-current value provided to the threshold value deriving section 18 may not fluctuate.

(2) In the case the electrical equipment 2 is switched from power-on to power-off

In this case, the average of measurements derived by the off-current average recording section 16d continues to decrease significantly. Accordingly, the output from the off-current average deriving section 16b (average of measurements of the current) continues to be lower than the recorded content of the off-current average recording section 16d (off-current value)−(the recorded content of the off-current range recording section 16e)/2. This results in that the off-current value provided to the threshold value deriving section 18 continues to be updated.

However, some time after the electrical equipment 2 is powered off, the current becomes approximately constant. The output from the off-current average deriving section 16b (average of measurements of the current) then no longer goes below the recorded content of the off-current average recording section 16d (off-current value)−(the recorded content of the off-current range recording section 16e)/2. This results in that the off-current value provided to the threshold value deriving section 18 may not fluctuate.

After the on-current value and the off-current value provided to the threshold value deriving section 18 thus become constant, the threshold value deriving section 18 subtracts the off-current value (e.g. 0) from the on-current value (e.g. Amax) and multiply by a predetermined coefficient (e.g. a value equal to or higher than 0.05 but equal to or lower than 0.65) to derive a threshold value Ath and provides it to the threshold value recording section 12.

The followed operations (i.e., determining the operational status (on or off) of the electrical equipment 2) are identical to those in the first embodiment and will not be described.

The sensor tag 1 according to the third embodiment automatically exhibits the same advantageous effects as that according to the first embodiment without using the on-current derivation instructing section 14a and the off-current derivation instructing section 16a (e.g. two buttons in total).

### Fourth Embodiment

The sensor tag (operational status determining apparatus) 1 according to a fourth embodiment differs from that according to the third embodiment in that the off-current deriving section 16 is arranged to derive an off-current value as a mode of measurements of the current while the electrical equipment 2 is powered off.

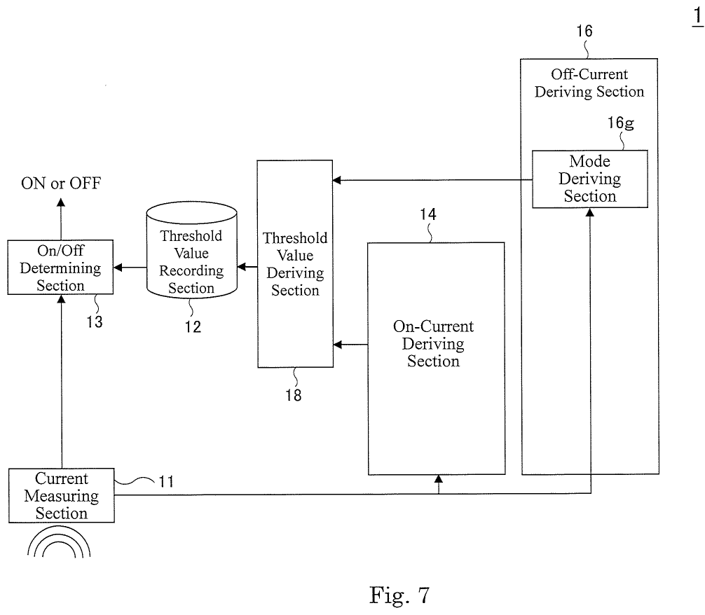

FIG. 7 is a functional block diagram illustrating the configuration of a sensor tag (operational status determining apparatus) 1 according to the fourth embodiment. The sensor tag 1 according to the fourth embodiment includes a current measuring section 11, a threshold value recording section 12, an on/off determining section 13, an on-current deriving section 14, an off-current deriving section 16, and a threshold value deriving section 18. Components identical to those in the third embodiment will hereinafter be designated by the same reference symbols to omit the description thereof.

The current measuring section 11, the threshold value recording section 12, the on/off determining section 13, and the threshold value deriving section 18 are identical to those in the (first and) third embodiment and will not be described. The on-current deriving section 14 is identical to that in the third embodiment (see FIG. 5) and will not be described.

The off-current deriving section 16 is arranged to derive the off-current value as a mode of measurements of the current while the electrical equipment 2 is powered off. The off-current deriving section 16 has a mode deriving section 16g. The mode deriving section 16g is arranged to derive the mode of measurements of the current by the current measuring section 11 as an off-current and provide it to the threshold value deriving section 18. Note here that the mode deriving section 16g is arranged to operate while the electrical equipment 2 is powered off.

Next will be described an operation according to the fourth embodiment.

First, the electrical equipment 2 is powered off. Here, upon the user causing the mode deriving section 16g to operate after verifying that the electrical equipment 2 is powered off, the mode deriving section 16g derives a mode of measurements of the current by the current measuring section 11 as an off-current and provides it to the threshold value deriving section 18.

The subsequent operation is identical to that “(1) In the case the electrical equipment 2 is switched from power-off to power-on” of the third embodiment and will not be described.

Further, the followed operations (i.e., determining the operational status (on or off) of the electrical equipment 2) are identical to those in the first embodiment and will not be described.

The sensor tag 1 according to the fourth embodiment exhibits the same advantageous effects as that according to the third embodiment.

The above-described embodiments may also be implemented as follows. A computer including a CPU, a hard disk, and a medium (USB memory, CD-ROM, or the like) reading device is caused to read a medium with a program recorded thereon that achieves the above-described components (e.g. the threshold value recording section 12, the on/off determining section 13, and the threshold value deriving section 18 of the sensor tag 1) and install the program in the hard disk. The above-described features can also be achieved in this manner.

### DESCRIPTION OF REFERENCE NUMERAL

1 Sensor Tag (Operational Status Determining Apparatus)
2 Electrical Equipment
4 Power Cable
6 Battery
11 Current Measuring Section
12 Threshold Value Recording Section
13 On/Off Determining Section
14 On-Current Deriving Section
15 On/Off-Current Derivation Instructing Section
16 Off-Current Deriving Section
17 Notifying Section
18 Threshold Value Deriving Section
Ath Threshold Value

What is claimed is:

1. An operational status determining apparatus, comprising:
a current measuring section arranged to measure a current through a power cable connected to an electrical equipment; and
an on/off determining section arranged to determine that the electrical equipment is powered on when the current is higher than a threshold value, while determine that the electrical equipment is powered off when the current is lower than the threshold value, wherein
the threshold value is:
equal to or higher than a current upper limit below which the electrical equipment is definitely powered off, and
equal to or lower than a current lower limit above which the electrical equipment is definitely powered on.

2. The operational status determining apparatus according to claim 1, wherein
the current measuring section is a non-contact sensor not in contact with the power cable.

3. The operational status determining apparatus according to claim 1, further comprising:
a threshold value deriving section arranged to derive the threshold value;
an on-current deriving section arranged to derive an on-current value at which the electrical equipment is powered on; and
an off-current deriving section arranged to derive an off-current value at which the electrical equipment is powered off, wherein
the threshold value deriving section is arranged to subtract the off-current value from the on-current value and multiply by a predetermined coefficient to derive the threshold value.

4. The operational status determining apparatus according to claim 3, wherein
the on-current deriving section is arranged to derive the on-current value as an average of measurements of the current.

5. The operational status determining apparatus according to claim 4, wherein
the on-current deriving section is arranged to, when the average of measurements of the current is higher than the on-current value+(a maximum of measurements of the current within a predetermined period of time−a minimum of measurements of the current within a predetermined period of time)/2, set the average of measurements of the current as a new on-current value.

6. The operational status determining apparatus according to claim 3, wherein
the off-current deriving section is arranged to derive the off-current value as an average of measurements of the current.

7. The operational status determining apparatus according to claim 6, wherein
the off-current deriving section is arranged to, when the average of measurements of the current is lower than the off-current value−(a maximum of measurements of the current within a predetermined period of time−a minimum of measurements of the current within a predetermined period of time)/2, set the average of measurements of the current as a new off-current value.

8. The operational status determining apparatus according to claim 3, wherein
the off-current deriving section is arranged to derive the off-current value as a mode of measurements of the current within a period of time within which the electrical equipment is powered off.

9. The operational status determining apparatus according to claim 3, further comprising:
an on-current derivation instructing section arranged to instruct the on-current deriving section to derive the on-current value; and
an off-current derivation instructing section arranged to instruct the off-current deriving section to derive the off-current value, wherein
the on-current derivation instructing section and the off-current derivation instructing section are separate from each other.

10. The operational status determining apparatus according to claim 3, further comprising an on/off-current derivation instructing section arranged to instruct the on-current deriving section and the off-current deriving section for derivation, wherein
the on/off-current derivation instructing section is arranged to:
when receiving a first operation, instruct the on-current deriving section for derivation, while
when receiving a second operation, instruct the off-current deriving section for derivation.

11. The operational status determining apparatus according to claim 10, further comprising a notifying section arranged to notify that the on/off-current derivation instructing section receives the first operation or the second operation.

12. An operational status determining method for determining an operational status of an electrical equipment with using a current measuring section arranged to measure a current through a power cable connected to the electrical equipment, comprising:
determining that the electrical equipment is powered on when the current is higher than a threshold value, while determining that the electrical equipment is powered off when the current is lower than the threshold value, wherein
the threshold value is:
equal to or higher than a current upper limit below which the electrical equipment is definitely powered off, and
equal to or lower than a current lower limit above which the electrical equipment is definitely powered on.

13. A non-transitory computer-readable medium including a program of instructions for execution by a computer to perform an operational status determining process for determining an operational status of an electrical equipment with using a current measuring section arranged to measure a current through a power cable connected to the electrical equipment, said operational status determining process comprising:
determining that the electrical equipment is powered on when the current is higher than a threshold value, while determining that the electrical equipment is powered off when the current is lower than the threshold value, wherein
the threshold value is:
equal to or higher than a current upper limit below which the electrical equipment is definitely powered off, and
equal to or lower than a current lower limit above which the electrical equipment is definitely powered on.
